(19) United States
(12) Patent Application Publication
(10) Pub. No.: US 2026/0167452 A1
(43) Pub. Date: Jun. 18, 2026

(54) REEL SORTING APPARATUS

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/874,766

(22) PCT Filed: Jul. 28, 2022
(86) PCT No.: PCT/JP2022/029094

§ 371 Date: Dec. 13, 2024

(51) Int. Cl. B65H 67/06; B65H 75/18; H05K 13/08

(52) U.S. Cl. CPC B65H 67/062; B65H 67/063; B65H 75/182; H05K 13/084; H05K 13/086; B65H 2701/17262

(57) ABSTRACT

A reel sorting apparatus includes a reel information acquisition section configured to acquire reel information about a reel around which a carrier tape configured to accommodate multiple components is wound, a determination section configured to execute determination processing of whether to supply the reel to a reel loading device that performs a loading operation of the reel to a feeder based on the acquired reel information, and a sorting section configured to sort the reel based on a result of the determination processing.

### TECHNICAL FIELD

The present disclosure relates to a reel sorting apparatus.

### BACKGROUND ART

The reel sorting apparatus is applied to, for example, a setup operation of production of a board product. The setup operation includes a reel loading operation to a feeder. Patent Literature 1 discloses a configuration in which a reel is automatically loaded to a tape feeder. The reel loading operation is switched depending on, for example, the type of the feeder or the type of the reel according to the production, whether to perform the reel loading operation by manual operation of a worker or using the reel loading device.

### CITATION LIST

### Patent Literature

Patent Literature 1: International Publication No. 2021/106026

### BRIEF SUMMARY

### Technical Problem

However, multiple types of reels are mixed and stored in a reel warehouse regardless of the type of reel loading operation. Therefore, when multiple reels used for the production are unloaded from the reel warehouse and loaded to the feeder, it is necessary to sort the reel according to the type of the reel loading operation.

An object of the present description is to provide a reel sorting apparatus capable of improving the efficiency of a setup operation.

The present description discloses a reel sorting apparatus including: a reel information acquisition section configured to acquire reel information about a reel around which a carrier tape configured to accommodate multiple components is wound; a determination section configured to execute determination processing of whether to supply the reel to a reel loading device that performs a loading operation of the reel to a feeder based on the acquired reel information; and a sorting section configured to sort the reel based on a result of the determination processing.

### Advantageous Effects

According to such a configuration, since reels are sorted by determining whether the reels are to be supplied to the reel loading device, sorting processing by a worker can be omitted, and efficiency of a setup operation can be improved.

### BRIEF DESCRIPTION OF DRAWINGS

FIG. 1 is a plan view schematically illustrating a setup device.

FIG. 2 is a perspective view illustrating a reel supply device to which a reel sorting apparatus is applied.

FIG. 3 is an enlarged view of a reel holding section illustrated in FIG. 2.

FIG. 4 is a front view of the reel holding section.

FIG. 5 is a functional block diagram of a reel loading device.

FIG. 6 is a flowchart illustrating reel sorting processing.

FIG. 7 is a perspective view illustrating a discharge unit according to a modification of the embodiment.

### DESCRIPTION OF EMBODIMENTS

A setup device to which a reel sorting apparatus is applied will be described with reference to the drawings. The setup device is a device that executes or supports various setup operations as preparation for producing a board product. In the present embodiment, a setup device that executes a reel loading operation of loading a reel to a tape feeder as a setup operation will be exemplified.

### 1. Setup Device 10

Setup device 10 is installed, for example, in an off-line setup area between a warehouse for storing components (not illustrated) and a production line in a production facility of a board product. In the off-line setup area, the operation of loading reel 92 to feeder 91 can be automatically performed by setup device 10, and be manually performed by a worker. When multiple types of setup devices 10 corresponding to the type of feeder 91 are installed, setup devices 10 may be switched and used. Further, between the off-line setup area and the warehouse, and between the off-line setup area and the production line, an automated guided vehicle and the worker can convey feeder 91 and the components.

### 1-1. Reel Loading Device 11

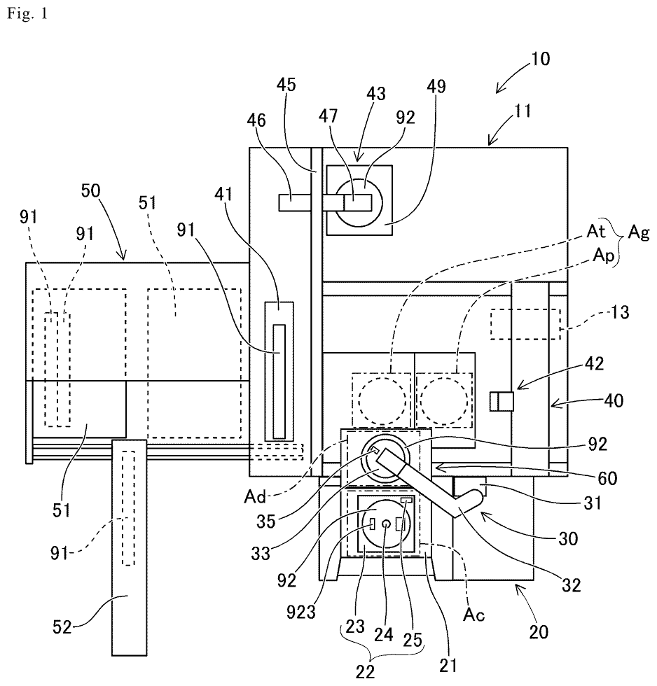

As illustrated in FIG. 1, setup device 10 includes reel loading device 11. Reel loading device 11 is a reel work device that executes a reel loading operation to feeder 91. Reel loading device 11 includes reel supply device 20 and reel attachment/detachment device 40.

### 1-1-1. Reel Supply Device 20

Reel supply device 20 temporarily holds multiple reels 92 carried in from the outside, and supplies reel 92 necessary for reel attachment/detachment device 40. Reel supply device 20 detachably supports reel holding section 22 on an upper surface of pedestal 21. Reel holding section 22 stacks and holds multiple reels 92 in a horizontal posture (a posture in which a rotation axis of reel 92 is oriented in a vertical direction). Reel 92 held by reel holding section 22 may include not only an unused reel but also a reel that has been partially used.

Reel holding section 22 holds multiple reels 92 by having round rod-shaped holding shaft 24 provided upward from the center of circular plate-shaped holding plate 23 and passing through a center hole of reel 92. Holding section code 25 indicating identification information (ID) for specifying reel holding section 22 is attached to an upper surface of holding plate 23. Holding section code 25 is used to manage multiple reels 92 held by reel holding section 22.

Reel supply device 20 includes reel transfer device 30 serving as a moving device that moves reel 92 to reel attachment/detachment device 40. Reel transfer device 30 is provided above pedestal 21. Reel transfer device 30 includes arm 32 that is provided to be liftable and lowerable with respect to column 31 extending in the vertical direction and to be rotatable around a vertical axis.

Arm 32 is provided with collection section 33 capable of extending and contracting in a horizontal direction. Collection section 33 detachably collects reel 92. Various aspects may be adopted as a collection method of collection section 33. For example, collection section 33 may grip the peripheral edge and the center hole of reel 92, or may pick up and collect the upper surface (flange surface in the horizontal posture) of reel 92 by a negative pressure air.

Collection section 33 is provided with reader 35. Reader 35 reads holding section code 25 of reel holding section 22. Reader 35 can read reel code 923 attached to uppermost reel 92 held by reel holding section 22 or to reel 92 collected by collection section 33. Reel code 923 indicates identification information (ID) that specifies reel 92.

Reel supply device 20 configured as described above is configured to supply multiple reels 92 which are carried in carry-in area Ac and held by reel holding section 22. When reel transfer device 30 drives arm 32 and collection section 33, reel supply device 20 places one reel 92 collected from reel holding section 22 in target area Ag (placement area Ap or temporary placement area At) on reel attachment/detachment device 40 side in a state in which reel 92 is in the horizontal posture.

Further, in the present embodiment, reel transfer device 30 moves collected reels 92 to discharge area Ad based on control by reel sorting apparatus 80 described later. Details of reel sorting apparatus 80 and the operation of reel transfer device 30 will be described later.

### 1-1-2. Reel Attachment/Detachment Device 40

Reel attachment/detachment device 40 performs an operation of setting reel 92 necessary for production to feeder 91, and an operation of removing reel 92 that became no longer necessary for production from feeder 91. Reel attachment/detachment device 40 includes feeder holding section 41 that holds feeder 91 carried in from feeder supply device 50 to be described later.

When feeder 91 is held by feeder holding section 41, feeder 91 is electrically connected to setup device 10 via a connector (not illustrated). As a result, feeder 91 is in a state of being able to communicate with control device 13 of setup device 10, which will be described later, and is in a state in which it is possible to operate a drive device that feeds and moves carrier tape 922 paid out from loaded reel 92.

Reel attachment/detachment device 40 includes setting device 42 that sets reel 92 to feeder 91 held by feeder holding section 41. Setting device 42 collects reel 92 in the horizontal posture in placement area Ap and changes the posture to a vertical posture (posture in which the rotation axis of reel 92 is oriented in a horizontal direction). Setting device 42 moves reel 92 in the vertical posture to feeder 91, and causes feeder 91 to hold reel 92.

In placement area Ap described above, reel 92 to be attached to feeder 91 held by feeder holding section 41 is placed in the horizontal posture. Further, in temporary placement area At, when it is necessary to change the order in which setting device 42 sets multiple reels 92 to feeder 91, reel 92 on which the set order is postponed is temporarily placed in the horizontal posture.

Setting device 42 has such a tape loading function that feeder 91 implements a loading state in which carrier tape 922 paid out from reel 92 can be fed by the drive device. Specifically, setting device 42 includes, for example, an articulated robot and an image processing device. Setting device 42 recognizes a leading end portion of carrier tape 922 by the image processing device. Setting device 42 grips the leading end portion of carrier tape 922 with the finger of the articulated robot, and engages a sprocket hole of carrier tape 922 with a sprocket constituting the drive device of feeder 91.

As a result, feeder 91 is set in a loading state in which reel 92 used for production is set and carrier tape 922 can be fed and moved. Feeder 91 on which reel 92 is set is removed from feeder holding section 41 and carried out to feeder supply device 50.

Reel attachment/detachment device 40 includes removal device 43 that removes reel 92 from feeder 91 held by feeder holding section 41. Removal device 43 moves movable base 46 along guide rail 45, and removes reel 92 set on feeder 91 by collection section 47 provided on movable base 46. Removal device 43 changes removed reel 92 from the vertical posture to the horizontal posture, and inserts reel 92 into storage box 49 provided in the device.

### 1-2. Feeder Supply Device 50

As illustrated in FIG. 1, setup device 10 includes feeder supply device 50. Feeder supply device 50 is installed side by side on reel loading device 11, and temporarily holds multiple feeders carried in from the outside, and supplies feeder 91 necessary for reel loading device 11. Feeder supply device 50 includes feeder accommodation section 51 that is detachably provided and feeder conveyance section 52.

Feeder accommodation section 51 is accommodated alongside other feeder accommodation sections 51 in an accommodation space of a housing. Feeder accommodation section 51 is formed in a box shape having an opening portion in the horizontal direction. Feeder accommodation section 51 supports feeder 91 with multiple slots formed in the bottom surface. When feeder 91 is held in feeder accommodation section 51, feeder 91 is communicably connected to setup device 10 via a connector (not illustrated).

Feeder conveyance section 52 is configured to be movable between feeder accommodation section 51 and feeder holding section 41. Feeder conveyance section 52 takes out arbitrary feeder 91 from feeder accommodation section 51 and carries feeder 91 in feeder holding section 41. When unnecessary reel 92 is removed from feeder 91 and reel 92 necessary for production to be executed is loaded to feeder 91 by reel loading device 11, feeder conveyance section 52 carries out feeder 91 from feeder holding section 41 and accommodates feeder 91 in a predetermined slot of feeder accommodation section 51.

### 1-3. Control Device 13

As illustrated in FIG. 1, setup device 10 includes control device 13. Control device 13 controls operations of reel loading device 11 and feeder supply device 50, and executes various operations to feeder 91. The above-described operation includes, in addition to the reel loading operation in the setup operation, the operation of simply removing reel 92 in order to store feeder 91 in a state where reel 92 is not loaded in a warehouse or the like.

Control device 13 obtains multiple reels 92 held by reel holding section 22 carried into carry-in area Ac based on the reading result of holding section code 25 by reader 35 of reel transfer device 30. Further, control device 13 obtains uppermost reel 92 held by reel holding section 22 or reel 92 collected by collection section 33 of reel transfer device 30 based on the reading result of reel code 923 by reader 35.

Control device 13 obtains feeder 91 held by feeder holding section 41 and feeder 91 accommodated in the feeder accommodation section 51 by communication. Based on the instruction of the setup operation, control device 13 loads reel 92 corresponding to predetermined feeder 91, or loads reel 92 to feeder 91 to be loaded in.

Further, when reel 92 is loaded to feeder 91, control device 13 generates association information. When reel 92 is removed from feeder 91, control device 13 deletes the association information. The generation and deletion of the association information are shared by a management device that is the higher-level of setup device 10 as necessary.

### 2. Reel Sorting Apparatus 80

### 2-1. Overview of Reel Sorting Apparatus 80

For example, carrier tape 922 accommodating the components and feeder 91 corresponding to carrier tape 922 are selected and used according to the production from multiple types. For example, the reel loading operation is automatically performed by setup device 10 when reel loading device 11 is compatible with the type of feeder 91, and is manually performed by the worker when reel loading device 11 is not compatible with the type of feeder 91.

However, multiple types of reels 92 are mixed and stored in the reel warehouse storing reel 92 conveyed to an off-line setup area regardless of whether the reel loading operation is performed by setup device 10. Therefore, it is necessary to sort reel 92 in accordance with the type of the reel loading operation (for example, automatic/manual) before performing the reel loading operation. In the present embodiment, a configuration is adopted in which the efficiency of the setup operation can be improved by automatically performing the reel sorting processing using reel sorting apparatus 80.

Specifically, in the present embodiment, reel sorting apparatus 80 is incorporated in setup device 10. Reel sorting apparatus 80 sorts reels 92 before being moved from carry-in area Ac to target area Ag (temporary placement area At and placement area Ap) in cooperation with reel supply device 20. Accordingly, reel 92 is sorted into a reel that is supplied to reel attachment/detachment device 40 of reel loading device 11 and a reel that is discharged from setup device 10.

Reels 92 sorted to be discharged from setup device 10 are discharged in various forms to be taken out by the worker or an automated guided vehicle. Reel sorting apparatus 80 may individually discharge reels 92 to be discharged or may collectively discharge multiple reels 92. Reel sorting apparatus 80 may return reel 92 to be discharged to carry-in area Ac or may move to discharge area Ad different from target area Ag and carry-in area Ac.

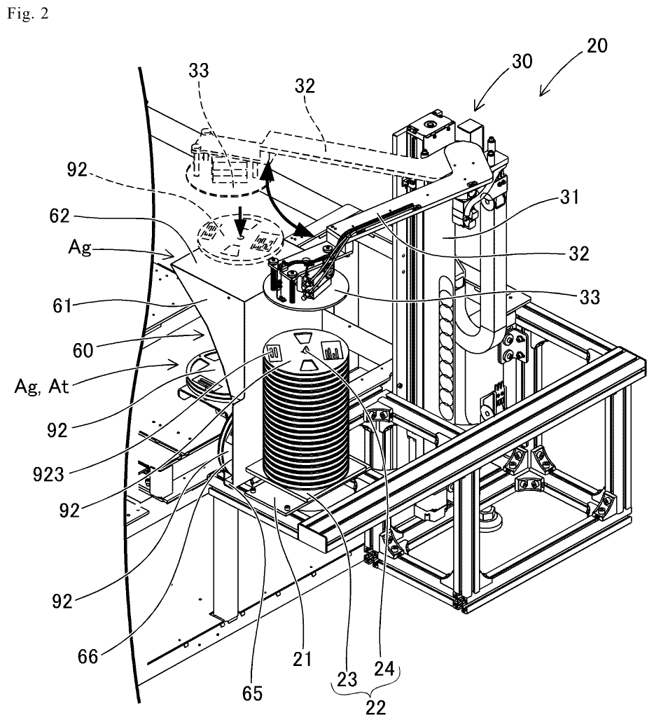

In the present embodiment, a configuration in which reel 92 is individually moved to discharge area Ad to be discharged is adopted. In the present embodiment, as illustrated in FIG. 1, discharge unit 60 that assists discharge of reel 92 is installed in discharge area Ad. In the present embodiment, discharge area Ad is set in a movable range of reel transfer device 30 between carry-in area Ac and target area Ag when viewed from above. As illustrated in FIG. 2, discharge unit 60 is configured to be able to insert reel 92 in the horizontal posture held by collection section 33 of reel transfer device 30.

### 2-2. Configuration of Discharge Unit 60

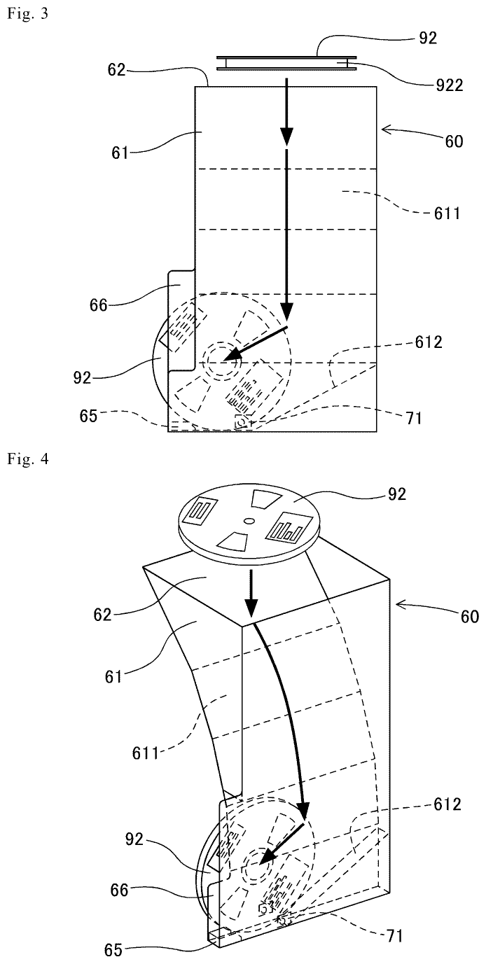

Discharge unit 60 is configured to be able to hold one reel 92 in discharge area Ad. As illustrated in FIGS. 3 and 4, discharge unit 60 includes chute 61 as a main body. Chute 61 is formed with inlet 62 into which reel 92 in the horizontal posture can be inserted. Chute 61 is formed with curved first slope 611 so that the posture of reel 92 gradually changes to the vertical posture while making inserted reel 92 in the horizontal posture slide downward.

Further, second slope 612 is formed at a lower portion of chute 61 to support an outer edge of reel 92 that is changed to the vertical posture. Second slope 612 is formed to be inclined around the horizontal axis with respect to the horizontal surface, and rotates reel 92 to be supported by its own weight. Stopper 65 is provided at the lowermost portion of second slope 612. Stopper 65 comes into contact with reel 92 rolling on second slope 612 downward to restrict the rotation of reel 92.

Discharge port 66 that exposes a portion of reel 92 held by second slope 612 and stopper 65 to the outside is formed in the lower portion of chute 61. Discharge port 66 is an opening for taking out formed larger than the outer diameter of reel 92 at a side surface on one side (left side in FIG. 4) in the width direction of chute 61. As described above, when reel 92 in the horizontal posture is inserted through inlet 62, discharge unit 60 changes the posture of reel 92 to the vertical posture while making reel 92 slide downward, and holds reel 92 in a moved state so that reel 92 can be taken out from discharge port 66 on the side surface.

In the present embodiment, discharge unit 60 is provided with reel sensor 71. Reel sensor 71 detects reel 92 whose movement is restricted by stopper 65, and transmits a signal to reel sorting apparatus 80. When reel 92 held by discharge unit 60 is taken out by the worker, reel sensor 71 is in a state in which reel 92 is not detected, and stops transmission of the signal to reel sorting apparatus 80.

### 2-3. Configuration of Reel Sorting Apparatus 80

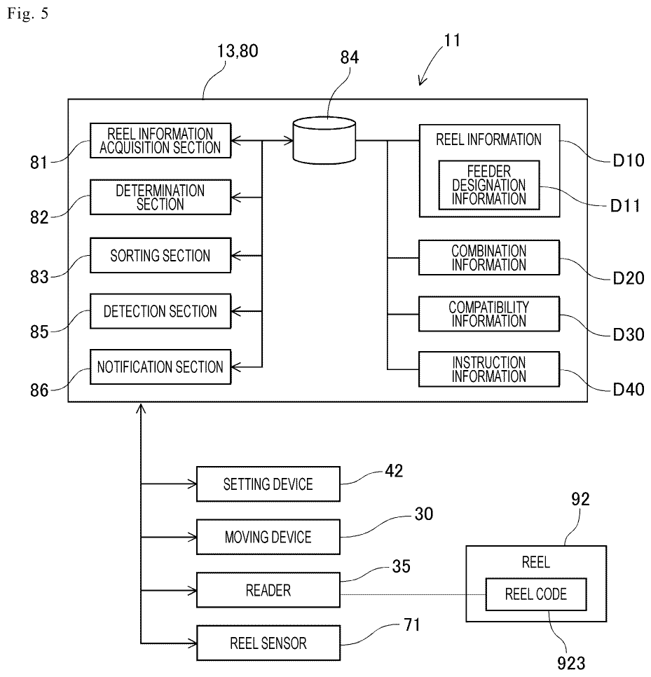

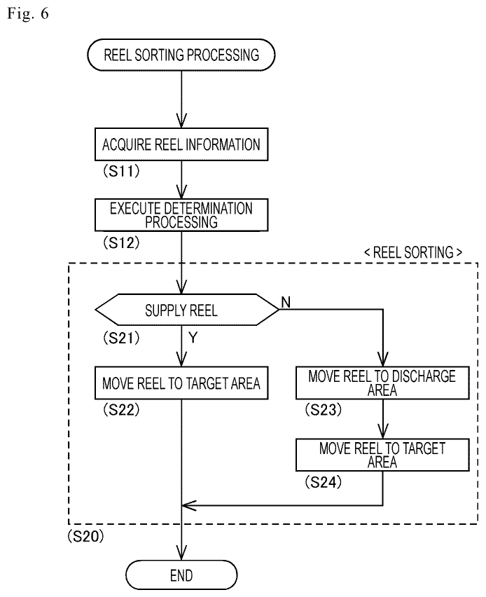

In the present embodiment, as illustrated in FIG. 5, reel sorting apparatus 80 is incorporated in control device 13 of setup device 10. Reel sorting apparatus 80 is configured to control the operation of reel transfer device 30 by using various functions of control device 13, input signals from various sensors, and acquire various information from communication with a higher-level management device. As illustrated in FIG. 6, reel sorting apparatus 80 executes the reel sorting processing.

### 2-3-1. Reel Information Acquisition Section 81

As illustrated in FIG. 5, reel sorting apparatus 80 includes reel information acquisition section 81. Reel information acquisition section 81 acquires reel information D10 about reel 92 around which carrier tape 922 accommodating multiple components is wound. In the present embodiment, reel information acquisition section 81 acquires reel information D10 corresponding to the identification information (ID) read from reader 35 of reel transfer device 30 serving as the moving device of reel 92 (S11 in FIG. 6).

Specifically, reel information acquisition section 81 transmits the identification information of reel 92 indicated by reel code 923 read by reader 35 to the management device, and acquires reel information D10 corresponding to the identification information by inputting reel information D10. When reader 35 reads holding section code 25, the identification information of reel holding section 22 may be transmitted to the management device, and the identification information of multiple reels 92 held by reel holding section 22 may be acquired in the stacking order of reels 92.

In the present embodiment, reel information D10 includes feeder designation information D11 that designates the type of feeder 91 to which reel 92 is loaded. Here, there are multiple types of feeders 91 as described above. For example, the type of feeder 91 includes a type in which the width dimension is different according to the type of carrier tape 922, and a type in which carrier tape 922 for replenishment is preliminarily set in addition to carrier tape 922 in use and carrier tape 922 for replenishment is automatically fed and moved when carrier tape 922 in use is finished.

Feeder designation information D11 of reel information D10 designates one or more types of feeders 91 which allow loading of reel 92. The type of designated feeder 91 includes a type in which the reel loading operation can be executed by setup device 10 and a type in which the reel loading operation can be executed only by the manual operation of the worker. When the type of feeder 91 to be loaded on predetermined reel 92 is not designated, reel information D10 does not include feeder designation information D11.

### 2-3-2. Determination Section 82

As illustrated in FIG. 5, reel sorting apparatus 80 includes determination section 82. Determination section 82 executes processing of determining whether to supply reel 92 to reel loading device 11 based on acquired reel information D10 (S12 in FIG. 6). In other words, determination section 82 determines whether to supply reel 92 carried into reel supply device 20 to reel attachment/detachment device 40 that executes loading operation in reel loading device 11.

Determination section 82 can execute the determination processing based on various conditions. For example, determination section 82 may execute the determination processing based on whether loading operation by reel loading device 11 can be performed for feeder 91 of the type designated by feeder designation information D11. Accordingly, the determination target reel 92 is determined to be supplied to reel attachment/detachment device 40 when designated feeder 91 corresponds to reel loading device 11.

It should be noted that determination section 82 may determine whether the loading operation by reel loading device 11 can be performed for feeder 91, based on compatibility information D30 indicating whether loading operation by reel loading device 11 is possible for each type of feeder 91 and each type of reel 92. In compatibility information D30, operations that can be performed by setup device 10 for each type are recorded for feeder 91 and reel 92 that can be carried into setup device 10.

Further, even when feeder designation information D11 is not included in reel information D10, determination section 82 may determine the type of feeder 91 to which reel 92 is loaded and the type of reel 92 based on combination information D20, and execute the determination processing. Combination information D20 is information indicating a combination of feeder 91 and reel 92 used for each production of the board product.

Further, determination section 82 may execute the determination processing based on instruction information D40 instructing omission of the loading operation regardless of whether the loading operation is possible by reel loading device 11. In principle, determination section 82 executes determination processing based on whether carried-in reel 92 and loading target feeder 91 correspond to setup device 10. However, in setup device 10, in a case where the planned production is canceled, or in a case where the worker needs to quickly perform the setup operation by manual operation and convey feeder 91 and components to the production line by interrupting the production, the planned setup operation may become unnecessary.

In consideration of such circumstances, information for instructing omission (skip) of the loading operation is recorded in instruction information D40 in accordance with a change in the production plan or the like. In the determination processing based on various conditions, determination section 82 determines that reel 92 is not to be supplied to reel loading device 11 so as not to execute the loading operation when the instruction to skip the loading operation is finally made.

### 2-3-3. Sorting Section 83

As illustrated in FIG. 5, reel sorting apparatus 80 includes sorting section 83. Sorting section 83 sorts reels 92 based on the result of the determination processing (S20 in FIG. 6). In the present embodiment, sorting section 83 sorts reels 92 by switching the movement target of reel 92 by reel transfer device 30 based on the result of the determination processing.

Specifically, reel transfer device 30 transfers reel 92 carried into carry-in area Ac to placement area Ap or temporary placement area At in target area Ag as the initial movement target. When it is determined by the determination processing that reel 92 is to be supplied (S21 of FIG. 6: Yes), sorting section 83 moves reel 92 to target area Ag (S22). Meanwhile, when it is determined by the determination processing that reel 92 is not supplied (S21: No), sorting section 83 switches the movement target to discharge area Ad and moves reel 92 to discharge area Ad (S23).

Reel 92 moved to discharge area Ad is released from collection section 33 of reel transfer device 30 and inserted from inlet 62 above inlet 62 of discharge unit 60. Reel 92 is guided to discharge port 66 while being changed from the horizontal posture to the vertical posture by chute 61. Reel 92 is held by discharge unit 60 in a state in which reel 92 can be taken out to the outside in a state where the movement of reel 92 is restricted by stopper 65.

Discharge unit 60 of the present embodiment is capable of holding only one reel 92. Then, when it becomes necessary to discharge reel 92 again during the reel sorting processing that continues after reel 92 has been inserted into discharge unit 60, sorting section 83 waits to insert reel 92 into discharge unit 60 until earlier discharged reel 92 is taken out by the worker or the like. When earlier discharged reel 92 is taken out, sorting section 83 resumes the insertion operation of reel 92.

### 2-3-4. Storage Section 84

As illustrated in FIG. 5, reel sorting apparatus 80 includes storage section 84. Storage section 84 is configured with a hard disk device or a storage device such as a flash memory. Storage section 84 records a control program necessary for executing the setup operation, operation instruction information corresponding to the production plan acquired from the higher-level management device, and the like. An execution log of the determination processing by determination section 82 and an execution log of the sorting operation by sorting section 83 are recorded in storage section 84.

In the present embodiment, storage section 84 stores reel information D10, combination information D20, compatibility information D30, and instruction information D40. These pieces of information are input to the worker via, for example, an input device (not illustrated) provided in setup device 10, and are acquired by communication from a higher-level management device. Further, the information is appropriately updated according to the change of the production plan and maintained in a state synchronized with the management device.

### 2-3-5. Detection Section 85

As illustrated in FIG. 5, reel sorting apparatus 80 includes detection section 85. Detection section 85 detects reel 92 held by discharge unit 60. Specifically, when reel 92 inserted into discharge unit 60 is guided to discharge port 66 and is held in a state where the movement of reel 92 is restricted by stopper 65, reel sensor 71 provided in discharge unit 60 detects reel 92, and the signal is transmitted.

Detection section 85 recognizes that there is reel 92 that can be taken out in discharge unit 60 while the signal is being input. For example, when reel 92 is taken out from discharge unit 60 by the worker and the transmission of the signal by reel sensor 71 is stopped, detection section 85 recognizes that discharge unit 60 does not hold reel 92.

### 2-3-6. Notification Section 86

As illustrated in FIG. 5, reel sorting apparatus 80 includes notification section 86. When it is determined by the determination processing that reel 92 is not supplied (S21: No in FIG. 6), or when reel 92 is moved to a predetermined area based on the result of the determination processing (S22, S23), notification section 86 notifies the worker of a notification according to the result of the determination processing (S24). For example, when reel 92 to be discharged is detected by detection section 85 (when reel 92 is moved to discharge area Ad as a result of the determination processing), notification section 86 executes notification processing for giving notification to the worker.

The notification processing is performed by lighting of a display lamp, notification to a terminal device carried by the worker, or the like. Further, notification section 86 may execute notification processing when it is determined that reel 92 is not supplied to reel attachment/detachment device 40 of reel loading device 11 by determination section 82 regardless of the detection result by detection section 85. Further, when reel 92 is returned to original carry-in area Ac based on the result of the determination processing, notification section 86 may notify the worker of the fact.

When the above-described notification processing is executed, the worker can recognize that reel 92 to be discharged is present in setup device 10. Thus, the worker is prompted to take out reel 92 from setup device 10, and the setup operation to be performed by the manual operation can be started early.

### 3. Effect According to Configuration of Embodiment

According to the above configuration, since the sorting is performed by determining whether to supply reel 92 to reel loading device 11, the reel sorting processing is automatically performed, and the reel sorting processing operation by the worker can be omitted. Further, when reel 92 is discharged from setup device 10 by the reel sorting processing, the worker can recognize that loading processing according to manual operation is necessary. As a result, the efficiency of the setup operation can be improved.

### 4. Modification of Embodiment

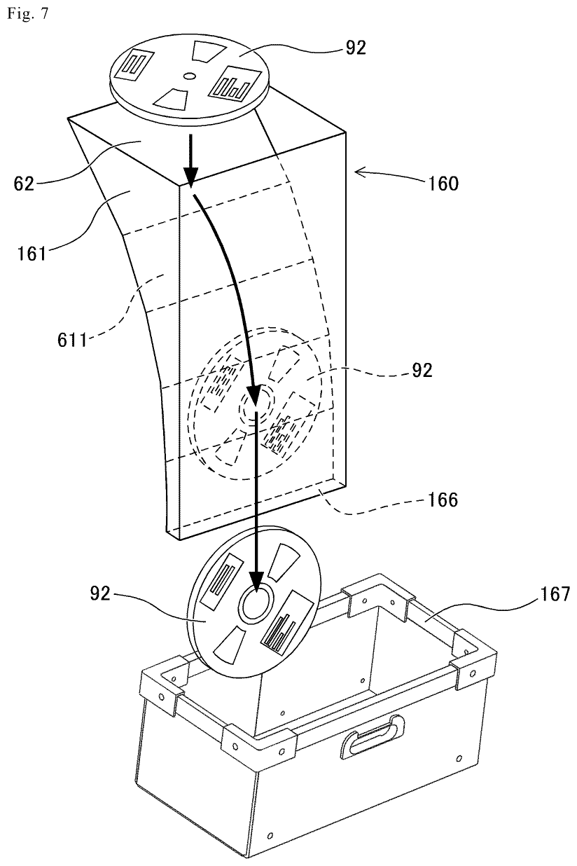

4-1. Discharge Unit In the embodiment, reel sorting apparatus 80 is configured to insert reel 92 determined not to be supplied to reel loading device 11 to discharge unit 60 installed in discharge area Ad. Discharge unit 60 is capable of holding only one reel 92. Meanwhile, as illustrated in FIG. 7, discharge unit 160 of reel loading device 11 may include reel box 167 capable of accommodating multiple reels 92 in discharge area Ad.

Discharge unit 160 includes chute 161 in which inlet 62 into which reel 92 in the horizontal posture can be inserted is formed. Chute 161 is formed with curved first slope 611 so that the posture of reel 92 gradually changes to the vertical posture while making inserted reel 92 in the horizontal posture slide downward. Discharge port 166 through which reel 92 whose posture is changed to the vertical posture falls downward is formed in a lower portion of chute 61. Reel box 167 is disposed below discharge port 166.

According to such a configuration, along with the execution of the reel sorting processing, multiple reels 92 determined not to be supplied to reel loading device 11 are discharged to reel box 167. Thus, the worker can collectively take out multiple reels 92 accumulated in reel box 167. In addition, in the configuration in which discharge unit 160 is installed, when the number of reels 92 that are determined not to be supplied to reel loading device 11 and inserted into discharge unit 160 reaches a predetermined value or more, reel sorting apparatus 80 may notify the worker of this.

In the embodiment and the modification described above, reel loading device 11 includes discharge units 60 and 160. Meanwhile, reel loading device 11 need not include discharge units 60 and 160. Specifically, when it is determined by the determination processing that reel 92 is not supplied, sorting section 83 switches the movement target from target area Ag to carry-in area Ac and returns reel 92 to carry-in area Ac.

Reader 35 may read reel code 923 of uppermost reel 92 held by reel holding section 22 without collection section 33 collecting uppermost reel 92. At this time, when it is determined that reel 92 is not supplied to the reel loading device, the processing of moving reel 92 to carry-in area Ac by sorting section 83 is omitted, and notification processing by notification section 86 is executed as necessary.

### 4-2. Reel Sorting Apparatus 80

In the embodiment, reel sorting apparatus 80 is incorporated in setup device 10 installed in the off-line setup area. Meanwhile, reel sorting apparatus 80 may be configured as an external device of setup device 10 as long as the reel sorting processing can be executed with respect to multiple reels 92 before being carried into setup device 10.

For example, similarly to setup device 10, the reel sorting apparatus may be configured as a device dedicated to the reel sorting processing installed side by side with setup device 10 in the off-line setup area. In such a configuration, the reel sorting apparatus has the same functions as those of reel transfer device 30 of setup device 10, and sorts reel 92 to be supplied to reel loading device 11 of setup device 10 and other reels 92.

The reel sorting apparatus may be incorporated in a warehouse for storing reel 92. In such a configuration, the reel sorting apparatus acquires reel information D10 for multiple reels 92 unloaded from the warehouse, determines whether to supply reels 92 to reel loading device 11, and sorts reels 92 based on the result of the determination processing. For example, multiple retrieval ports are provided in advance in the warehouse or multiple reel holding sections 22 are supported on the retrieval port, and multiple reels 92 are unloaded from the warehouse in a sorted state. Even in such a configuration, the same effect as in the embodiment is obtained.

### REFERENCE SIGNS LIST

10: setup device, 11: reel loading device, 13: control device, 20: reel supply device, 30: reel transfer device (moving device), 35: reader, 40: reel attachment/detachment device, 41: feeder holding section, 42: setting device, 43: removal device, 50: feeder supply device, 60, 160: discharge unit, 61, 161: chute, 611: first slope, 612: second slope, 62: inlet, 65: stopper, 66, 166: discharge port, 167: reel box, 71: reel sensor, 80: reel sorting apparatus, 81: reel information acquisition section, 82: determination section, 83: sorting section, 84: storage section, 85: detection section, 86: notification section, 91: feeder, 92: reel, Ag: target area, Ap: placement area, At: temporary placement area, Ad: discharge area, Ac: carry-in area, D10: reel information, D11: feeder designation information, D20: combination information, D30: compatibility information, D40: instruction information

1. A reel sorting apparatus comprising:
a reel information acquisition section configured to acquire reel information about a reel around which a carrier tape configured to accommodate multiple components is wound;
a determination section configured to execute determination processing of whether to supply the reel to a reel loading device that performs a loading operation of the reel to a feeder based on the acquired reel information; and
a sorting section configured to sort the reel based on a result of the determination processing.

2. The reel sorting apparatus according to claim 1,
wherein the reel information includes feeder designation information designating a type of the feeder loaded with the reel, and
the determination section executes the determination processing based on whether loading operation by the reel loading device can be performed for the feeder of the type designated by the feeder designation information.

3. The reel sorting apparatus according to claim 1, further comprising: a storage section configured to store combination information indicating a combination of the feeder and the reel used for each production of a board product, and compatibility information indicating whether the loading operation is possible by the reel loading device for each type of the feeder and each type of the reel,
wherein the determination section determines a type of the feeder on which the reel is to be loaded and a type of the reel based on the reel information and the combination information, and executes the determination processing based on the compatibility information.

4. The reel sorting apparatus according to claim 3,
wherein the storage section stores instruction information for instructing omission of the loading operation regardless of whether the loading operation by the reel loading device is possible, and
the determination section executes the determination processing based on the instruction information.

5. The reel sorting apparatus according to claim 1,
wherein the reel loading device includes
a setting device configured to set the reel placed in a target area to the feeder,
a moving device configured to collect the reel carried into a carry-in area and move the reel to the target area, and
a reader configured to read identification information attached to the reel,
the reel information acquisition section acquires the reel information corresponding to the identification information read by the reader, and
the sorting section sorts the reel by switching a movement target of the reel by the moving device based on a result of the determination processing.

6. The reel sorting apparatus according to claim 5, wherein the sorting section moves the reel to the target area when it is determined by the determination processing that the reel is to be supplied.

7. The reel sorting apparatus according to claim 5, wherein the reader reads the identification information for the reel in a state collected by the moving device, and
the sorting section moves the reel so that the reel is returned to the carry-in area when it is determined by the determination processing that the reel is not to be supplied.

8. The reel sorting apparatus according to claim 5, wherein the sorting section moves the reel to a discharge area different from the target area and the carry-in area when it is determined by the determination processing that the reel is not to be supplied.

9. The reel sorting apparatus according to claim 8, further comprising:
a discharge unit configured to hold one reel in the discharge area; and
a detection section configured to detect the reel held by the discharge unit.

10. The reel sorting apparatus according to claim 8, further comprising: a reel box configured to accommodate multiple reels in the discharge area.

11. The reel sorting apparatus according to claim 1, further comprising: a notification section configured to notify a worker of a notification according to a result of the determination processing when it is determined by the determination processing that the reel is not to be supplied, or when the reel is moved to a predetermined area.
